(19) United States
(12) Patent Application Publication
(10) Pub. No.: US 2025/0219612 A1
(43) Pub. Date: Jul. 3, 2025

(54) GALLIUM NITRIDE SURFACE ACOUSTIC WAVE RESONATOR

(71) Applicants: Tsinghua University, Beijing (CN); Hon Hai Precision Industry Co., Ltd., New Taipei (TW)

(72) Inventors: LEI XIAO, Beijing (CN); Yang Wei, Beijing (CN); Jing Wang, Beijing (CN); Shou-Shan Fan, Beijing (CN)

(21) Appl. No.: 18/978,221

(22) Filed: Dec. 12, 2024

(30) Foreign Application Priority Data
Dec. 27, 2023 (CN) 202311829707.9

(51) Int. Cl. H03H 9/02; H03H 9/145; H03H 9/25

(52) U.S. Cl. CPC H03H 9/02574; H03H 9/02637; H03H 9/02992; H03H 9/145; H03H 9/25

(57) ABSTRACT

A gallium nitride surface acoustic wave resonator comprises a substrate comprising an epitaxial growth surface; a carbon nanotube layer located on the substrate and comprising a plurality of holes, and the epitaxial growth surface of the substrate exposed through the plurality of holes; a gallium nitride layer located on the carbon nanotube layer; an interdigital transducer located on the gallium nitride layer; and two reflection grating units respectively located on both sides of the interdigital transducer.

### CROSS-REFERENCE TO RELATED APPLICATIONS

This application claims all benefits accruing under 35 U.S.C. § 119 from China Patent Application No. 202311829707.9, filed on Dec. 27, 2023, in the China National Intellectual Property Administration, the contents of which are hereby incorporated by reference.

### FIELD

The disclosure relates to the technical field of surface acoustic wave devices, and in particular to a gallium nitride (GaN) surface acoustic wave resonator.

### BACKGROUND

Surface acoustic wave (SAW) devices are widely used not only in the field of circuit filters, but also in mass sensing, temperature sensing, gas sensing, biochemical sensing, humidity sensing, and air pressure sensing due to their high operating frequency, high frequency quality factor, high sensitivity, and high stability. The quality factor of SAW devices is their most important technical indicator. The higher the quality factor of SAW devices as filters, the better the roll-off characteristics of the filter and the greater the out-of-band suppression. The higher the quality factor of SAW devices as sensors, the higher the sensor sensitivity.

Material properties set on a substrate have a greater impact on the quality factor of surface acoustic wave devices.

### BRIEF DESCRIPTION OF THE DRAWINGS

Implementations of the present technology will now be described, by way of example only, with reference to the attached figures, wherein:

FIG. 1 is a schematic diagram of an exploded structure of a GaN SAW resonator provided in an embodiment of the present disclosure.

FIG. 2 is a schematic diagram of a cross-sectional structure of the GaN SAW resonator shown in FIG. 1.

FIG. 3 is a scanning electron microscope photo of a carbon nanotube film provided in an embodiment of the present disclosure.

FIG. 4 is a schematic diagram of a structure of carbon nanotube fragments in the carbon nanotube film shown in FIG. 3.

FIG. 5 is a scanning electron microscope photo of a carbon nanotube non-twisted wire provided in an embodiment of the present disclosure.

FIG. 6 is a scanning electron microscope photo of a carbon nanotube twisted wire provided in an embodiment of the present disclosure.

FIG. 7 is a scanning electron microscope photo of the sapphire substrate provided with a carbon nanotube layer in the GaN SAW resonator provided in an embodiment of the present disclosure.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to illustrate details and features of the present disclosure better.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “comprise, but not necessarily limited to”; it specifically indicates open-ended inclusion or membership in the so-described combination, group, series, and the like. The term of “first”, “second” and the like, are only used for description purposes, and should not be understood as indicating or implying their relative importance or implying the number of indicated technical features. Thus, the features defined as “first”, “second” and the like expressly or implicitly comprise at least one of the features. The term of “multiple times” means at least two times, such as two times, three times, etc., unless otherwise expressly and specifically defined.

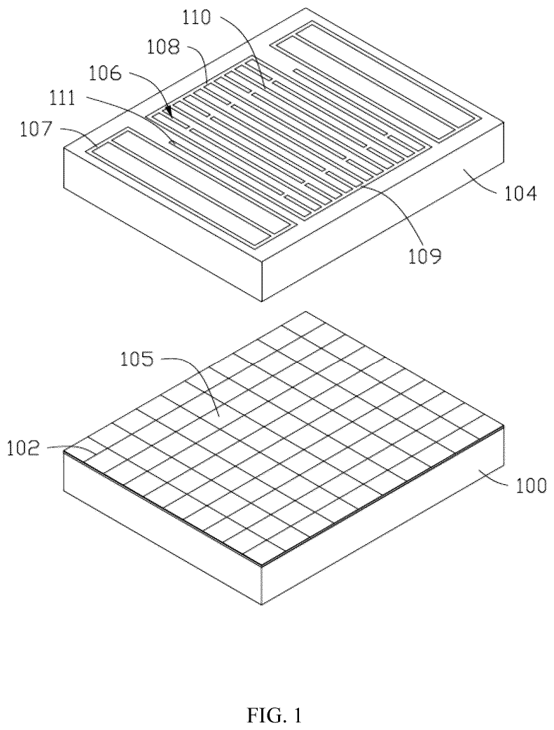

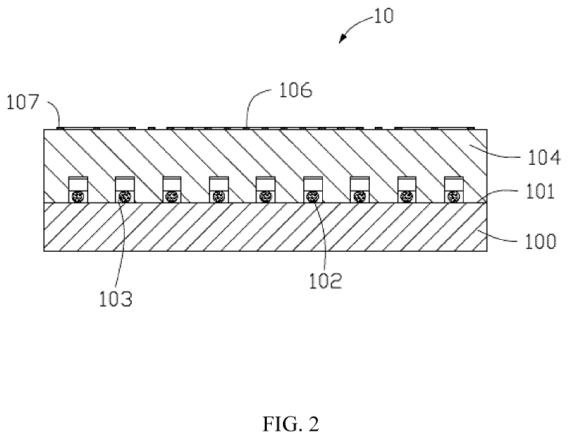

Referring to FIG. 1 and FIG. 2, a gallium nitride (GaN) surface acoustic wave resonator 10 is provided in an embodiment of the present disclosure. The gallium nitride surface acoustic wave resonator 10 comprises a substrate 100, a carbon nanotube layer 102, a gallium nitride layer 104, an interdigital transducer 106, and two reflective grating units 107 sequentially. The two reflective grating units 107 are respectively located on both sides of the interdigital transducer 106.

The substrate 100 comprises an epitaxial growth surface 101, which is a molecularly smooth surface and has impurities such as oxygen or carbon removed. A material of the substrate 100 can be GaAs, GaN, Si, SOI, AlN, SiC, MgO, ZnO, LiGaO2, LiAlO2 or Al2O3, etc. In one embodiment, the substrate 100 is a sapphire substrate.

The carbon nanotube layer 102 is a continuous integral structure comprising a plurality of carbon nanotubes. The plurality of carbon nanotubes in the carbon nanotube layer 102 extend in a direction substantially parallel to a surface of the carbon nanotube layer 102. When the carbon nanotube layer 102 is disposed on the epitaxial growth surface 101 of the substrate 100, the extension direction of the plurality of carbon nanotubes in the carbon nanotube layer 102 is substantially parallel to the epitaxial growth surface 101 of the substrate 100. In one embodiment, a thickness of the carbon nanotube layer is ranged from 1 nanometer to 100 micrometers. In another embodiment, a thickness of the carbon nanotube layer is ranged from 1 nanometer to 1 micrometer. In yet another embodiment, a thickness of the carbon nanotube layer is ranged from 1 nanometer to 200 nanometers. In the present embodiment, the thickness of the carbon nanotube layer is ranged from 10 nanometers to 100 nanometers.

The carbon nanotube layer 102 is a patterned structure, that is, the carbon nanotube layer 102 has a plurality of holes 105, and the plurality of holes 105 penetrate the carbon nanotube layer 102 from a thickness direction of the carbon nanotube layer 102. When the carbon nanotube layer 102 is disposed to cover the epitaxial growth surface 101 of the substrate 100, a portion of the epitaxial growth surface 101 of the substrate 100 corresponding to the hole 105 is exposed to facilitate the growth of the gallium nitride layer 104. The hole 105 can be a micropore or a gap. A size of the hole 105 is ranged from 10 nanometers to 500 micrometers. The size of the hole 105 is 10 nanometers to 300 micrometers, or 10 nanometers to 120 micrometers, or 10 nanometers to 80 micrometers, or 10 nanometers to 10 micrometers. The smaller the size of the hole 105, the more conducive it is to reduce the generation of dislocation defects in the process of growing the gallium nitride layer to obtain a high-quality gallium nitride layer 104. Preferably, the size of the hole 105 is 10 nanometers to 10 micrometers. Further, a duty ratio of the carbon nanotube layer 102 is 1:100 to 100:1, or 1:10 to 10:1, or 1:2 to 2:1, or 1:4 to 4:1. Preferably, the duty ratio is 1:4 to 4:1. The duty ratio refers to an area ratio of the portion of the epitaxial growth surface 101 occupied by the carbon nanotube layer 102 to the portion exposed through the hole 105 after the carbon nanotube layer 102 is arranged on the epitaxial growth surface 101 of the substrate 100.

The carbon nanotube layer 102 can also be directly grown on the epitaxial growth surface 101 of the substrate 100 by a chemical vapor deposition (CVD) method. In another embodiment, the carbon nanotube layer 102 can also be first grown on the surface of the silicon substrate and then transferred to the epitaxial growth surface 101 of the substrate 100.

Specifically, the carbon nanotube layer 102 can comprise a carbon nanotube film or a carbon nanotube wire. The carbon nanotube layer 102 can be a single-layer carbon nanotube film or comprises a plurality of stacked carbon nanotube films. The carbon nanotube layer 102 can also comprise a plurality of parallel carbon nanotube wires or a plurality of cross-arranged carbon nanotube wires. When the carbon nanotube layer 102 is a plurality of stacked carbon nanotube films, layers of carbon nanotube films should not be less than 100 layers. When the carbon nanotube layer 102 comprises a plurality of parallel carbon nanotube wires, a distance between two adjacent carbon nanotube wires is ranged from 0.1 micrometers to 200 micrometers, preferably, 10 micrometers to 100 micrometers. The space between the two adjacent carbon nanotube wires constitutes the hole 105 of the carbon nanotube layer 102. The gap length between the two adjacent carbon nanotube wires can be equal to the length of the carbon nanotube wire. The carbon nanotube film or carbon nanotube wire can be directly laid on the epitaxial growth surface 101 of the substrate 100 to form the carbon nanotube layer 102. By controlling layers of the carbon nanotube films or the distances between the carbon nanotube wires, the size of the hole 105 in the carbon nanotube layer 102 can be controlled.

The carbon nanotube film is a self-standing structure composed of a plurality of carbon nanotubes. The plurality of carbon nanotubes are preferably oriented and extended in a same direction. The preferred orientation means that the overall extension direction of most carbon nanotubes in the carbon nanotube film is basically in the same direction. Moreover, the overall extension direction of most carbon nanotubes is basically parallel to the surface of the carbon nanotube film. Furthermore, most of the carbon nanotubes in the carbon nanotube film are connected end to end by van der Waals force. Specifically, each carbon nanotube in the majority of carbon nanotubes extending in the same direction in the carbon nanotube film is connected end to end with the adjacent carbon nanotube in the extension direction by van der Waals force. There are a few randomly arranged carbon nanotubes in the carbon nanotube film, and these carbon nanotubes will not have a significant impact on the overall orientation arrangement of most carbon nanotubes in the carbon nanotube film. The self-standing carbon nanotube film does not require a large area of carrier support, but can be suspended as a whole and maintain its own film state as long as the supporting force is provided on both sides. That is, when the carbon nanotube film is placed (or fixed) on two supports set at a specific distance, the carbon nanotube film located between the two supports can be suspended and maintain its own film state. The self-standing is mainly achieved by the presence of continuous carbon nanotubes in the carbon nanotube film that are connected end to end by van der Waals force and extend.

Specifically, the majority of carbon nanotubes extending in the same direction in the carbon nanotube film are not absolutely straight and can be bent appropriately; or they are not arranged completely in the extension direction and can be appropriately deviated from the extension direction. Therefore, it cannot be ruled out that the carbon nanotubes in the majority of carbon nanotubes extending in the same direction in the carbon nanotube film can be partially in contact with each other.

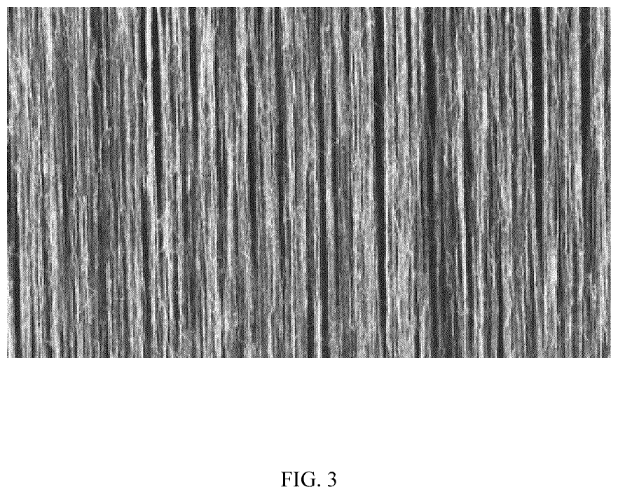

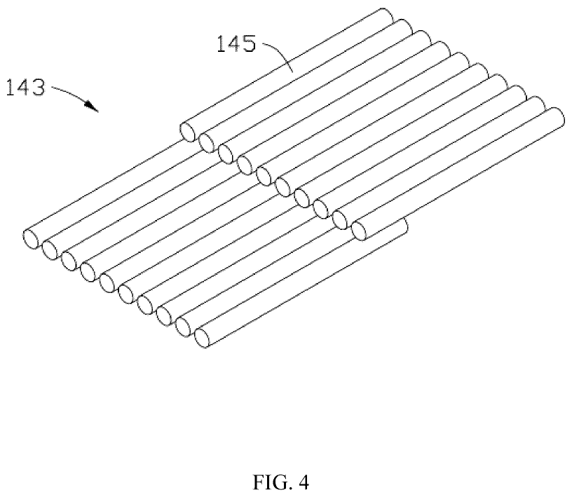

Please refer to FIGS. 3 and 4, the carbon nanotube film comprises a plurality of continuous and directionally extended carbon nanotube segments 143. The plurality of carbon nanotube segments 143 are connected end to end by van der Waals forces. Each carbon nanotube segment 143 comprises a plurality of mutually parallel carbon nanotubes 145, and the plurality of mutually parallel carbon nanotubes 145 are tightly bound by van der Waals forces. The carbon nanotube segment 143 has an arbitrary length, thickness, uniformity and shape. The carbon nanotube film can be obtained by directly pulling a portion of carbon nanotubes selected from a carbon nanotube array. The thickness of the carbon nanotube film is ranged from 1 nanometer to 100 micrometers. There are micropores or gaps between adjacent carbon nanotubes in the carbon nanotube film to form an hole 105, and the pore size or gap size of the micropore is less than 10 micrometers. Preferably, the thickness of the carbon nanotube film is 100 nanometers to 10 micrometers. The carbon nanotubes 145 in the carbon nanotube film are preferentially oriented and extend in the same direction.

When the carbon nanotube layer comprises a plurality of stacked carbon nanotube films, the extension directions of the carbon nanotubes in two adjacent carbon nanotube films form a cross angle, and the cross angle is greater than or equal to 0 degrees and less than or equal to 90 degrees.

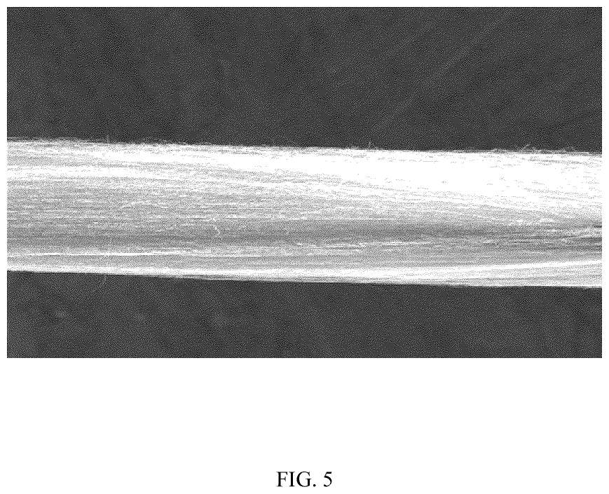

The carbon nanotube wire can be a non-twisted carbon nanotube wire or a twisted carbon nanotube wire. Both the non-twisted carbon nanotube wire and the twisted carbon nanotube wire are self-standing structures. Specifically, referring to FIG. 5, the non-twisted carbon nanotube wire comprises a plurality of carbon nanotubes extending in a direction parallel to the length of the non-twisted carbon nanotube wire. Specifically, the non-twisted carbon nanotube wire comprises a plurality of carbon nanotube segments, the plurality of carbon nanotube segments are connected end to end by van der Waals forces, and each carbon nanotube segment comprises a plurality of carbon nanotubes that are parallel to each other and tightly bound by van der Waals forces. The carbon nanotube segment has any length, thickness, uniformity and shape. The length of the non-twisted carbon nanotube wire is unlimited, and the diameter is 0.5 nanometers to 100 micrometers. The non-twisted carbon nanotube wire is obtained by treating the carbon nanotube film with an organic solvent. Specifically, the entire surface of the carbon nanotube film is soaked with an organic solvent, and under the action of the surface tension generated when the volatile organic solvent evaporates, the multiple carbon nanotubes in the carbon nanotube film that are parallel to each other are tightly combined by van der Waals force, so that the carbon nanotube film shrinks into a non-twisted carbon nanotube wire. The organic solvent is a volatile organic solvent, such as ethanol, methanol, acetone, dichloroethane or chloroform, and ethanol is used in this embodiment. Compared with the carbon nanotube film that has not been treated with an organic solvent, the non-twisted carbon nanotube wire treated with an organic solvent has a smaller specific surface area and lower viscosity.

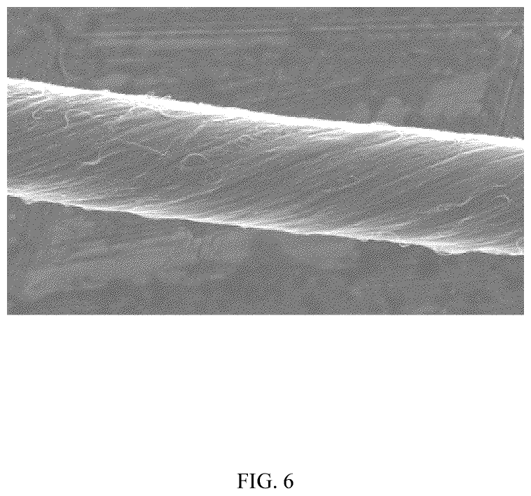

The twisted carbon nanotube wire is obtained by twisting the two ends of the carbon nanotube film in opposite directions using a mechanical force. Please refer to FIG. 6, the twisted carbon nanotube wire comprises a plurality of carbon nanotubes that extend spirally around the axial direction of the twisted carbon nanotube wire. Specifically, the twisted carbon nanotube wire comprises a plurality of carbon nanotube segments, which are connected end to end by van der Waals force, and each carbon nanotube segment comprises a plurality of carbon nanotubes that are parallel to each other and tightly bound by van der Waals force. The carbon nanotube segment has any length, thickness, uniformity and shape. The length of the twisted carbon nanotube wire is not limited, and the diameter is 0.5 nanometers to 100 micrometers. Further, a volatile organic solvent can be used to treat the twisted carbon nanotube wire. Under the action of the surface tension generated when the volatile organic solvent evaporates, the adjacent carbon nanotubes in the treated twisted carbon nanotube wire are tightly bound by van der Waals force, so that the specific surface area of the twisted carbon nanotube wire is reduced, and the density and strength are increased.

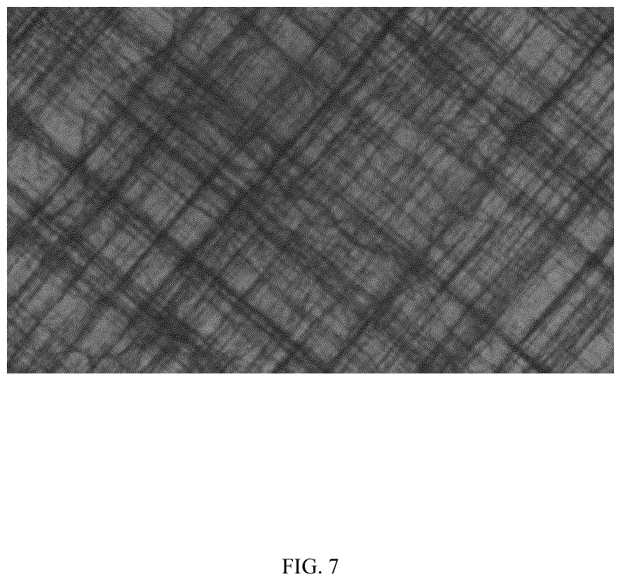

In this embodiment, please refer to FIG. 7, the carbon nanotube layer is a graphical structure, including 6 layers of stacked carbon nanotube films, and the cross angle formed by the extension directions of the carbon nanotubes in two adjacent carbon nanotube films is 90 degrees. That is, the extension directions of the carbon nanotubes in the two adjacent carbon nanotube films are perpendicular to each other. The carbon nanotube layer is formed with a plurality of holes, and the epitaxial growth surface of the substrate is exposed out from the plurality of holes.

The gallium nitride layer 104 is located on the epitaxial growth surface 101 of the substrate 100, covers the carbon nanotube layer 102, and is disposed in a plurality of holes 105 of the carbon nanotube layer 102 in contact with the epitaxial growth surface 101 of the substrate 100, that is, the gallium nitride layer 104 is grown in the plurality of holes 105 of the carbon nanotube layer 102. The gallium nitride layer 104 and the carbon nanotube layer 102 covered by it are arranged at intervals at a microscopic level, that is, a plurality of holes 103 are formed on the surface of the gallium nitride layer 104 in contact with the substrate 100, and the carbon nanotube layer 102 is disposed in the holes 103. Specifically, the carbon nanotubes in the carbon nanotube layer 102 are respectively disposed in the plurality of holes 103. The holes 103 are formed on the surface of the gallium nitride layer 104 in contact with the substrate 100, and the holes 103 are all blind holes in the thickness direction of the gallium nitride layer 104. In each hole 103, the carbon nanotubes are basically not in contact with the gallium nitride layer 104.

A method for growing the gallium nitride layer 104 can be molecular beam epitaxy (MBE), chemical beam epitaxy (CBE), reduced pressure epitaxy, low temperature epitaxy, selective epitaxy, liquid phase deposition epitaxy (LPE), metal organic vapor phase epitaxy (MOVPE), ultra vacuum chemical vapor deposition (UHVCVD), hydride vapor phase epitaxy (HVPE), or metal organic chemical vapor deposition (MOCVD).

Please refer to FIG. 1, the interdigital transducer 106 comprises a first bus bar 108, a second bus bar 109, a plurality of first interdigital electrodes 110 and a plurality of second interdigital electrodes 11. The first bus bar 108 and the second bus bar 109 are arranged at intervals relative to each other. The plurality of first interdigital electrodes 110 and the plurality of second interdigital electrodes 111 are alternately arranged between the first bus bar 108 and the second bus bar 109. The plurality of first interdigital electrodes 110 are led out from the first bus bar 108 and extend to the second bus bar 109. The plurality of second interdigital electrodes 111 are led out from the second bus bar 109 and extend to the first bus bar 108. In one embodiment, each of the plurality of first interdigital electrodes 110 comprises a first long interdigital electrode and a first short interdigital electrode, and the first long interdigital electrode and the first short interdigital electrode are arranged at intervals alternately. Each of the plurality of second interdigital electrodes 111 comprises a second long interdigital electrode and a second short interdigital electrode, and the second long interdigital electrode and the second short interdigital electrode are arranged at intervals alternately. The first long interdigital electrode and the second short interdigital electrode are arranged in a collinear manner, and the first short interdigital electrode and the second long interdigital electrode are arranged in a collinear manner. Two reflection grating units 107 are respectively arranged on both sides of the interdigital transducer 106, and the reflection grating unit 107 can reflect the acoustic wave energy to the interdigital transducer 106.

According to measurement and calculation, the quality of the gallium nitride layer manufactured on the sapphire substrate with the carbon nanotube layer of this embodiment has been significantly improved. The gallium nitride surface acoustic wave resonator manufactured on the sapphire substrate with the carbon nanotube layer of this embodiment has a quality factor improved by 33% compared with the gallium nitride surface acoustic wave resonator manufactured on the sapphire substrate. This shows that the introduction of the carbon nanotube layer improves the quality of the crystalline gallium nitride, thereby improving the performance of the gallium nitride surface acoustic wave resonator. When the gallium nitride surface acoustic wave resonator manufactured on the sapphire substrate with the nanotube layer is applied to various electronic devices, the performance of various electronic devices will be greatly improved.

The present disclosure uses a carbon nanotube layer as a mask and is arranged on the epitaxial growth surface of the substrate to grow a gallium nitride layer. Since the carbon nanotube layer is a patterned structure, the patterned carbon nanotube layer has multiple openings so that the epitaxial growth surface of the substrate is partially exposed through the multiple openings. When the substrate is used to grow a gallium nitride layer, the gallium nitride layer can only grow from the exposed epitaxial growth surface and then grow epitaxially laterally to form an integral whole, thereby reducing the contact area between the growing gallium nitride layer and the substrate, thereby reducing the stress between the gallium nitride layer and the substrate during the growth process. At the same time, the patterned carbon nanotube layer can effectively inhibit the extension of dislocation defects to the epitaxial surface, thereby reducing the defects of the gallium nitride layer, and can further improve the quality of the gallium nitride layer.

It is to be understood that the above-described embodiments are intended to illustrate rather than limit the present disclosure. Variations can be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described can be removed, others can be added, and the sequence of steps can be altered. The description and the claims drawn to a method may comprise some indication in reference to certain steps. However, the indication used is only to be viewed for identification purposes and not as a suggestion as to an order for the steps.

What is claimed is:

1. A gallium nitride surface acoustic wave resonator comprising, in said sequence:
a substrate comprising an epitaxial growth surface;
a carbon nanotube layer located on the epitaxial growth surface and comprising a plurality of holes exposing the epitaxial growth surface of the substrate exposed;
a gallium nitride layer located on the carbon nanotube layer;
an interdigital transducer located on the gallium nitride layer; and
two reflection grating units respectively located on respective sides of the interdigital transducer.

2. The gallium nitride surface acoustic wave resonator of claim 1, wherein the carbon nanotube layer comprises a plurality of carbon nanotubes, and the plurality of carbon nanotubes extends in a direction substantially parallel to a surface of the carbon nanotube layer.

3. The gallium nitride surface acoustic wave resonator of claim 1, wherein sizes of the plurality of holes are arranged from 10 nanometers to 500 micrometers.

4. The gallium nitride surface acoustic wave resonator of claim 3, wherein sizes of the plurality of holes are arranged from 10 nanometers to 10 microns.

5. The gallium nitride surface acoustic wave resonator of claim 1, wherein the carbon nanotube layer comprises at least one carbon nanotube film, the at least one carbon nanotube film comprises a plurality of carbon nanotubes, and the plurality of carbon nanotubes is oriented substantially in a same direction.

6. The gallium nitride surface acoustic wave resonator of claim 1, wherein the carbon nanotube layer comprises a plurality of carbon nanotube films stacked on top of each other.

7. The gallium nitride surface acoustic wave resonator of claim 6, wherein an orientation direction of the carbon nanotubes in each of the plurality of carbon nanotube films is substantially the same, and the plurality of carbon nanotube films is stacked on top of each other such that between the orientation directions of the carbon nanotubes in two adjacent carbon nanotube films define a cross angle that is greater than or equal to 0 degrees and less than or equal to 90 degrees.

8. The gallium nitride surface acoustic wave resonator of claim 1, wherein the carbon nanotube layer comprises a plurality of carbon nanotube wires, the plurality of carbon nanotube wire is substantially parallel to each other and spaced apart from each other.

9. The gallium nitride surface acoustic wave resonator of claim 1, wherein the carbon nanotube layer comprises a plurality of carbon nanotube wires, the plurality of carbon nanotube wires is not parallel to each other.

10. The gallium nitride surface acoustic wave resonator of claim 1, wherein the interdigital transducer comprises a first bus bar and a second bus bar arranged at a relative interval, a plurality of first interdigital electrodes and a plurality of second interdigital electrodes are alternately arranged between the first bus bar and the second bus bar, the plurality of first interdigital electrodes protrudes out from the first bus bar and extends to the second bus bar, and the plurality of second interdigital electrodes protrudes from the second bus bar and extends to the first bus bar.

11. The gallium nitride surface acoustic wave resonator of claim 10, wherein each of the plurality of first interdigital electrodes comprises a first long interdigital electrode and a first short interdigital electrode, the first long interdigital electrode and the first short interdigital electrode are interlaced arranged.

12. The gallium nitride surface acoustic wave resonator of claim 10, wherein each of the plurality of second interdigital electrodes comprises a second long interdigital electrode and a second short interdigital electrode, the second long interdigital electrode and the second short interdigital electrode are arranged at an interlaced interval; the first long interdigital electrode and the second short interdigital electrode are arranged in a collinear manner, and the first short interdigital electrode and the second long interdigital electrode are arranged in a collinear manner.
